(19) United States
(12) Patent Application Publication
(10) Pub. No.: US 2018/0012846 A1
(43) Pub. Date: Jan. 11, 2018

(54) GRAPHENE STRUCTURE

(71) Applicant: Kabushiki Kaisha Toshiba, Minato-ku (JP)

(72) Inventors: Hisao MIYAZAKI, Yokohama (JP); Takashi YOSHIDA, Kashiwa (JP); Masayuki KATAGIRI, Tsukuba (JP); Yuichi YAMAZAKI, Inagi (JP); Tadashi SAKAI, Yokohama (JP)

(73) Assignee: Kabushiki Kaisha Toshiba, Minato-ku (JP)

(21) Appl. No.: 15/446,244

(22) Filed: Mar. 1, 2017

(30) Foreign Application Priority Data
Jul. 5, 2016 (JP) 2016-133555

(51) Int. Cl. H01L 23/532

(52) U.S. Cl. CPC H01L 23/53276; H01L 23/53295

(57) ABSTRACT

A graphene structure of an embodiment includes multilayer graphene laminated with graphene sheets, and a first interlayer material being present between the graphene sheets of the multilayer graphene and containing a multimer of molybdenum oxide.

### CROSS-REFERENCE TO RELATED APPLICATION

This application is based upon and claims the benefit of priority from Japanese Patent Application No. 2016-133555, filed on Jul. 5, 2016; the entire contents of which are incorporated herein by reference.

### FIELD

Embodiments described herein relate to a graphene structure.

### BACKGROUND

According to the high integration and refinement of memories and the like, multilayer wirings in chips has also been required to be refined, and the most precedent flash memory is expected to have a half pitch of 10 nm or less in about 2020. Whereas, resistivity of currently used metal wirings of Cu or the like has been increased rapidly according to the refinement due to the increase of inelastic scattering and the like, thereby reaching the limit of the material. On the other hand, it is reported that nanocarbon materials represented by graphene and a carbon nanotube (CNT) exhibit significantly longer mean free paths, higher mobility and the like than those of metal even in a fine region, and are thus expected as next-generation fine wiring materials. Among them, graphene has possibility to be formed into a fine width wiring by a lithography process having good consistency with an existing large scale integration (LSI) process, thereby proceeding the development of a fine width integrated wiring based on multilayer graphene produced by chemical vapor deposition (CVD).

Multilayer graphene, which is just thinned as it is, has high resistance, and thus is not sufficient to be used as a wiring. Therefore, development of reducing the resistance by inserting (intercalating) an interlayer material into between layers of the multilayer graphene has been carried out. As the intercalation itself is a technique which has been widely examined with respect to graphite for over thirty years, many kinds of interlayer materials have been known, and a resistance reduction effect thereby has been shown. However, there is a problem that, if applying this intercalation to the fine width graphene, a doping effect is degraded according to the refinement, and the resistance reduction effect cannot be obtained. Further, there is a problem that, by graphene formed by low temperature CVD or the like which is required for the integration, it is difficult to obtain a sufficient resistance reduction effect regardless of a line width of the graphene.

### BRIEF DESCRIPTION OF THE DRAWINGS

FIG. 1 is a schematic cross-sectional view of a graphene structure of an embodiment;

FIG. 2 is a schematic cross-sectional view of a graphene structure of an embodiment;

FIG. 3 is a schematic cross-sectional view of a graphene structure of an embodiment;

FIG. 4 is a schematic cross-sectional view of a graphene structure of an embodiment;

FIG. 5 is a schematic cross-sectional view of a graphene structure of an embodiment;

FIG. 6 is a photographed image of a graphene structure of an example taken by a transmission electron microscope; and

FIG. 7 is a photographed image (A) of a graphene structure of an example taken by a scanning transmission electron microscope; an image (B) with carbon mapping on the photographed image (A); an image (C) with oxygen mapping on the photographed image (A); an image (D) with silicon mapping on the photographed image (A); an image (E) with chlorine mapping on the photographed image (A); and an image (F) with molybdenum mapping on the photographed image (A).

### DETAILED DESCRIPTION

A graphene structure of an embodiment includes multilayer graphene laminated with graphene sheets, and a first interlayer material being present between the graphene sheets of the multilayer graphene and containing a multimer of molybdenum oxide.

### First Embodiment

Embodiments will be described below with reference to the drawings. Elements denoted by the same reference codes represent the similar ones. Incidentally, the drawings are just schematic and conceptual, and relation between a thickness and a width of each part and a ratio of sizes of parts are not necessarily the same as the real ones. Further, even in the case of representing the same part, dimensions or ratios may be illustrated differently in the respective figures.

A graphene structure of a first embodiment includes a multilayer graphene and a first interlayer material. The multilayer graphene is laminated with plural graphene sheets. The first interlayer material is present between the plural graphene sheets and contains a multimer of molybdenum oxide.

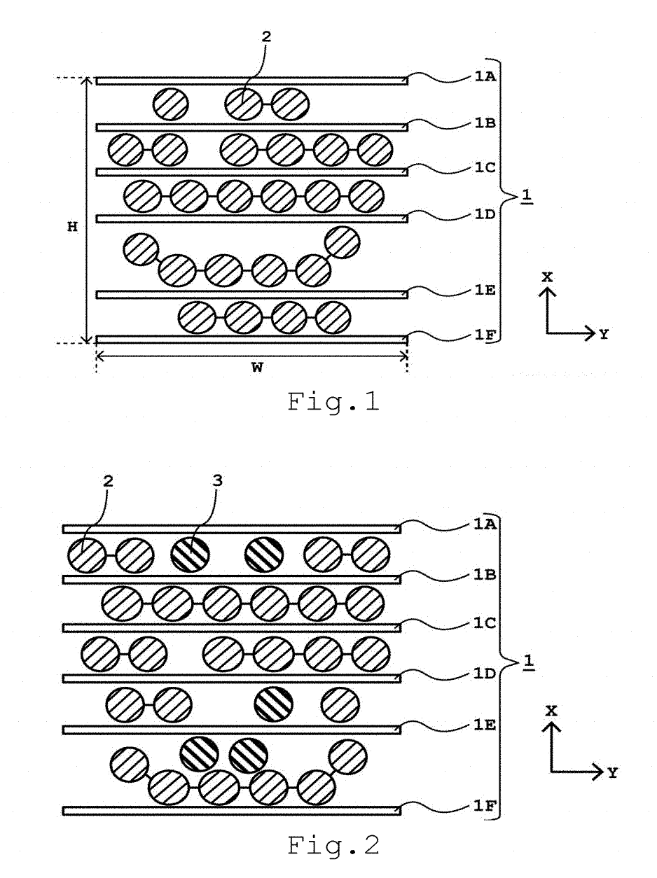

FIG. 1 is a schematic cross-sectional view of the graphene structure of the first embodiment.

The graphene structure of FIG. 1 includes: a multilayer graphene 1 that is a laminate of plural planar graphene sheets 1A to 1F; and a first interlayer material 2 present between the plural planar graphene sheets. A lamination direction of the planar graphene sheets 1A to 1F is denoted by an X-direction, and a width direction of the planar graphene sheets 1A to 1F is denoted by a Y-direction. A Z-direction, which is not illustrated in FIG. 1, is perpendicular to an X-Y plane. The Z-direction is a length direction in the case of using the multilayer graphene 1 as a wiring. The width direction of the multilayer graphene 1 is orthogonal to both of the lamination direction of the graphene sheets and a longitudinal direction of the multilayer graphene 1.

The multilayer graphene 1 that is the laminate of the plural planar graphene sheets is obtained by laminating the two or more planar graphene sheets so that their sheet surfaces may face each other. The multilayer graphene 1 is, for example, a laminated graphene obtained by laminating graphene sheets, each of which has a planar part, such as graphene nanoribbon, and does not include a laminate of graphene sheets having no planar part such as multilayer carbon nanotubes. The planar graphene sheets 1A to 1F are respectively atomic layers of carbon atoms having hexagonal lattice structures, which are bonded with each other along a Y-Z plane direction in FIG. 1. The planar graphene sheets 1A to 1F may partly include: carbon atoms having a pentagonal lattice structure or carbon atoms having a heptagonal lattice structure, beside the carbon atoms having a hexagonal lattice structure; a grain boundary (excluding ends of the graphene sheets); and a defect. Further, a compound for suppressing leakage of the interlayer material may be bonded to an end of the planar graphene sheet. Each of the planar graphene sheets 1A to 1F may be a monoatomic layer made of carbon atoms, or may be a monoatomic layer made of carbon atoms, some of which are bonded with oxygen, nitrogen atoms or the like. Moreover, the multilayer graphene 1 preferably has a wiring shape, for example, a thin line shape having a linear part or a thin line shape having both of a linear part and a folded part. Both ends of the multilayer graphene 1 having the wiring shape in the wiring length direction (Z-direction) are electrically connected with electrodes of a semiconductor element or the like. In the embodiment, the graphene structure represents a structure in which the interlayer material is present between the layers of the multilayer graphene 1. Herein, “between the layers of the multilayer graphene 1” means between the planar graphene sheets that face each other in the lamination direction.

The graphene structure of the embodiment is used for, for example, a wiring in a semiconductor device. The graphene structure of the embodiment is preferably used for a fine wiring (a conductive part) that serves as a signal transmission line in a semiconductor device. As such a semiconductor device adopting the graphene structure of the embodiment, processors such as a micro-processing unit (MPU) and a graphic processing unit (GPU) can be exemplified. Other than these, storage devices such as a dynamic random access memory (DRAM), an NAND flash memory and a crosspoint-type memory can be exemplified as the semiconductor device adopting the graphene structure of the embodiment. Further, a field programmable gate array (FPGA), a complex programmable logic device (CPLD), a system on chip (SoC) including the above-described processors and storage devices, and the like can also be exemplified as the semiconductor device adopting the graphene structure of the embodiment.

The configuration of the embodiment is effective, if a wiring width of the multilayer graphene 1 is 3 μm or less, which is likely to cause leakage of the interlayer material. More specifically, a wiring width W of the multilayer graphene 1 is preferably 5 nm or more and 20 nm or less, because an effect of suppressing the leakage of the interlayer material present between the layers of the multilayer graphene 1 can be significant. The wiring width W of the multilayer graphene 1 is more preferably 5 nm or more and 10 nm or less. In the graphene structure of the embodiment, much of the interlayer material is present also in a region that is 5 nm from the end of the multilayer graphene 1 toward a center thereof, where the interlayer material is likely to be leaked. In this region, the interlayer material is likely to be leaked, whereby the graphene structure of the embodiment has low resistance regardless of the wiring width of the multilayer graphene 1. The wiring width of the multilayer graphene 1 can be measured by being observed with a scanning transmission electron microscope or a transmission electron microscope.

The multilayer graphene 1 of the embodiment is a laminate of, for example, ten to about hundred layers of planar graphene sheets. A thickness H of the multilayer graphene 1 varies according to the number of laminated layers of the planar graphene sheets and the interlayer material, and is typically 5 nm or more and 100 nm or less. The multilayer graphene 1 exhibits the effects of the embodiment, regardless of whichever monocrystal graphene or multicrystal graphene it is. In the case where the multilayer graphene 1 is multicrystal graphene, since the multilayer graphene 1 is likely to be oxidized from its defect or grain boundary, it is favorable in the point that the interlayer material prevents leakage of the monomer interlayer material or the like from the defect or the grain boundary. The multicrystal graphene is produced by, for example, a low temperature CVD method.

The first interlayer material 2 is present between the plural planar graphene sheets. The first interlayer material 2 is a multimer of molybdenum oxide or a mixture of a monomer and a multimer of molybdenum oxide. The first interlayer material 2 preferably contains a multimer of molybdenum oxide. The multimer of molybdenum oxide is a compound having two or more monomers of molybdenum oxide that are bonded with each other. Molybdenum oxide has a high work function, and functions as a dopant that performs p-type doping to the multilayer graphene 1. In addition, molybdenum oxide is preferable in the point that it is oxide and thus exhibits stability between the layers of the multilayer graphene 1. Further, at least one kind or more among: a second interlayer material 3; a third interlayer material 4; and a fourth interlayer material 5, which will be described below, may also be present between the plural planar graphene sheets. Incidentally, the stability stated in the embodiment represents interlayer stability that means the difficulty of the leakage of the interlayer material from between the layers.

In the case where the interlayer material is absent between the layers, a distance between the layers of the multilayer graphene 1 is 0.335 nm. The interlayer distance can be increased. In the embodiment, since the multimer of molybdenum oxide is present between the layers of the multilayer graphene 1, the interlayer distance can be increased more than a case where a low-molecule compound is present. More specifically, the interlayer distance is 0.7 nm or more and 3.0 nm or less.

The first interlayer material 2 contains the multimer of molybdenum oxide, and thus is present between the layers of the multilayer graphene 1 more stably than the case of containing the monomer of molybdenum oxide. In the light of the interlayer stability, the first interlayer material 2 is preferably a multimer having four or more monomers of molybdenum oxide that are bonded with each other, and is more preferably a multimer having ten or more monomers of molybdenum oxide that are bonded with each other. Thus, the graphene structure of the embodiment becomes to have a configuration in which the interlayer material functioning as a dopant is present stably between the layers of the multilayer graphene 1, whereby a resistant reduction state of the wiring can be stable. Further, the multimer of molybdenum oxide has a merit that its high interlayer stability can suppress the leakage of other interlayer material. In the case where the other interlayer material functions as a dopant to the graphene, the multimer of molybdenum oxide stabilizes the doping effect of the other interlayer material, thereby further contributing to the resistant reduction of the graphene structure.

The multimer of molybdenum oxide is represented by a chemical formula as (MoO₃)ₙ. Here, n is an integer of 2 or more. Further, n is preferably an integer of 1,000 or less. The multimer of molybdenum oxide is, for example, oxide of a multimer of molybdenum chloride.

Moreover, the graphene structure of the embodiment may have a configuration illustrated in the schematic view of FIG. 2. The graphene structure shown in the schematic view of FIG. 2 includes: the multilayer graphene 1 that is the laminate of the plural planar graphene sheets 1A to 1F; and the first interlayer material 2 and the second interlayer material 3 that are present between the plural planar graphene sheets. In the case where the second interlayer material 3 is included in the graphene structure of the embodiment, the second interlayer material 3 is preferably present while it is mixed at least with the first interlayer material 2. The second interlayer material 3 is preferably a compound having both of the doping effect and the interlayer stability, which is specifically molybdenum oxychloride. Molybdenum oxychloride is an interlayer material which has lower stability than that of molybdenum oxide, but has a higher doping effect. Molybdenum oxychloride is, for example, incomplete oxide of molybdenum chloride. The second interlayer material 3 preferably contains molybdenum oxychloride (MoOₓCl_{y}; x is 1 or 2, and y is an integer of 1 or more and 4 or less).

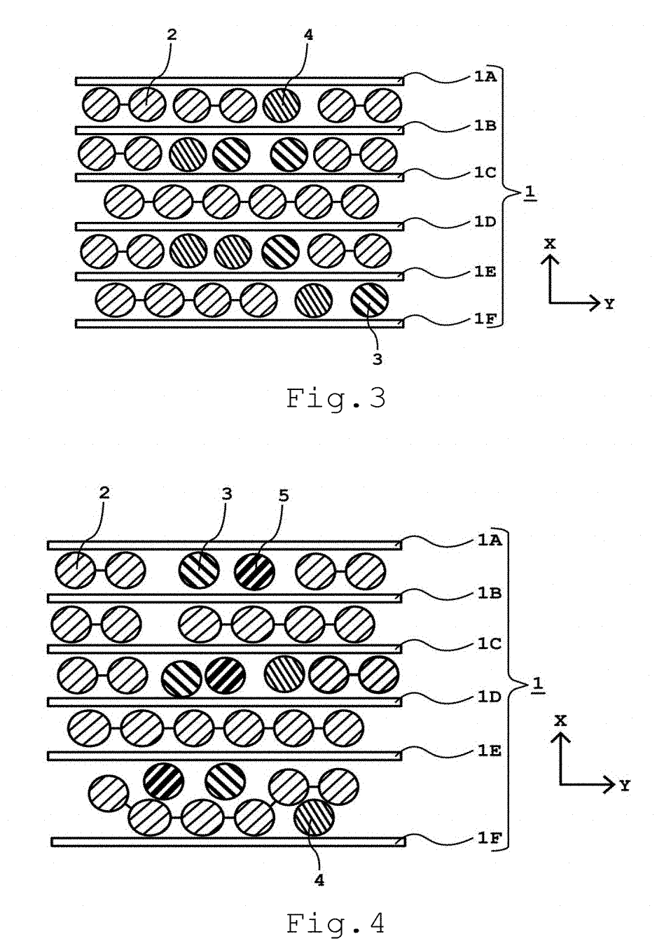

Moreover, the graphene structure of the embodiment may have a configuration illustrated in the schematic view of FIG. 3. The graphene structure shown in the schematic view of FIG. 3 includes: the multilayer graphene 1 that is the laminate of the plural planar graphene sheets 1A to 1F; the first interlayer material 2, the second interlayer material 3 and the third interlayer material 4 that are present between the plural planar graphene sheets. In the case where the third interlayer material 4 is included in the graphene structure of the embodiment, the third interlayer material 4 is preferably present while it is mixed at least with the first interlayer material 2. The third interlayer material 4 is preferably a compound having a high doping effect, which is specifically molybdenum chloride (MoCl₅). The third interlayer material 4 preferably contains a multimer of molybdenum chloride (MoCl₅). Molybdenum chloride has lower interlayer stability but has a higher doping effect than those of molybdenum oxide and molybdenum oxychloride. Molybdenum chloride itself is likely to be leaked from between the plural planar graphene sheets, but such leakage can be prevented by molybdenum oxide or molybdenum oxychloride. Incidentally, the third interlayer material 4 is oxidized so as to generate the first interlayer material 2 and the second interlayer material 3.

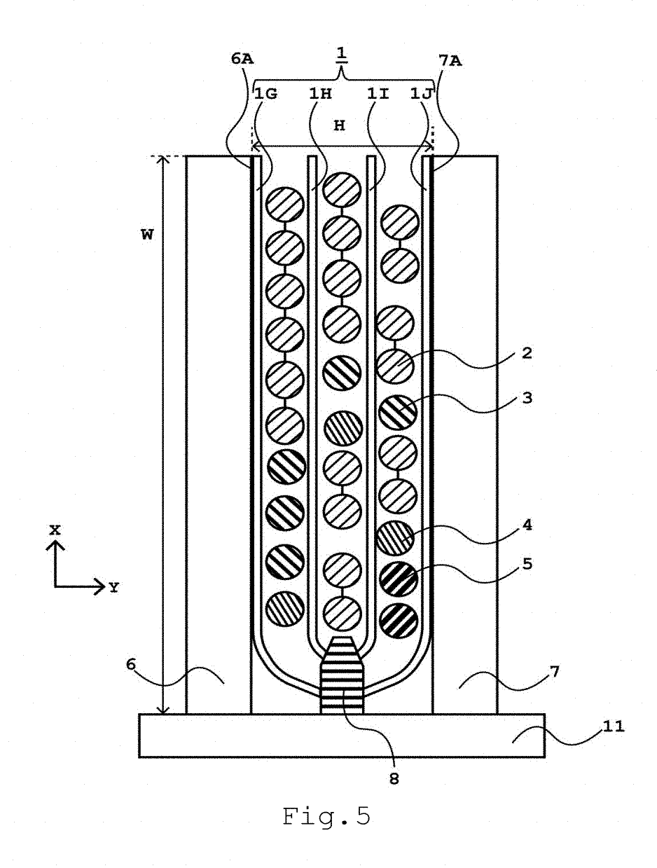

Further, the graphene structure of the embodiment may have a configuration illustrated in the schematic view of FIG. 4. The graphene structure shown in the schematic view of FIG. 4 includes: the multilayer graphene 1 that is the laminate of the plural planar graphene sheets 1A to 1F; the first interlayer material 2, the second interlayer material 3, the third interlayer material 4 and the fourth interlayer material 5 that are present between the plural planar graphene sheets. In the case where the fourth interlayer material 5 is included in the graphene structure of the embodiment, the fourth interlayer material 5 is preferably present while it is mixed at least with the first interlayer material 2. The fourth interlayer material 5 is, for example, chlorine (molecule) generated by oxidation reaction of the third interlayer material 4. Chlorine has lower interlayer stability but has a higher doping effect than those of molybdenum oxide and molybdenum oxychloride. Chlorine itself is likely to be leaked from between the plural planar graphene sheets, but such leakage can be prevented by molybdenum oxide or molybdenum oxychloride.

Next, a method for producing the graphene structure of the first embodiment will be described. The method for producing the graphene structure includes: inserting molybdenum chloride as the third interlayer material 4 into between the layers of the multilayer graphene 1; and performing oxidation treatment to the multilayer graphene 1 in which the third interlayer material 4 is inserted. The third interlayer material 4 is oxidized so as to generate the first interlayer material 2.

A member having the multilayer graphene 1 which is the laminate of the plural planar graphene sheets 1A, 1B, 1C, 1D, 1E and 1F are laminated on a substrate, is treated in an atmosphere containing gas of the third interlayer material 4. The multilayer graphene 1 may be processed into a wiring shape by providing a catalyst film on the substrate, which is not illustrated, and being grown from the catalyst film; may be transcribed onto the substrate and then processed into a wiring shape; or may be processed into a wiring shape and then transcribed onto a substrate. The multilayer graphene 1 may be monocrystal graphene or multicrystal graphene.

A temperature for treating the multilayer graphene 1 in the atmosphere containing the gas of the third interlayer material 4 is preferably, for example, 200° C. or more and 300° C. or less. A time period for treating the multilayer graphene 1 in the atmosphere containing the gas of the third interlayer material 4 is not limited particularly. In order to insert much of the third interlayer material 4 into between the layers of the multilayer graphene 1, the treating time is preferably 30 minutes or more. The atmosphere containing the gas of the third interlayer material 4 may further contain carrier gas such as inert gas and halogen gas. By inserting (intercalating) the third interlayer material 4 into between the layers of the multilayer graphene 1, the interlayer distance of the multilayer graphene 1 is increased.

The third interlayer material 4, which is inserted into between the layers of the multilayer graphene 1, is oxidized so as to generate the first interlayer material 2 from the third interlayer material 4. When shifting from the step of inserting the third interlayer material 4 into between the layers of the multilayer graphene 1 to the present step, a temperature of the environment is preferably lower than the temperature during the insertion of the third interlayer material 4. Then, the first interlayer material 2 is preferably generated by: replacing the atmosphere containing the gas of the third interlayer material 4 with an oxidizing atmosphere at 5° C. or more and 100° C. or less; and then oxidizing the third interlayer material 4 at 5° C. or more and 100° C. or less. Further, in order to generate the multimer of molybdenum oxide, from the step of replacing the gas of the third interlayer material 4 with the oxidizing atmosphere to the step of oxidizing the third interlayer material 4, a total pressure of the atmosphere is preferably 1 atm or more and 3 atm or less. A time period for the oxidation treatment is preferably, for example, 1 minute or more and 3 hours or less.

The oxidizing atmosphere contains at least one kind among oxygen, ozone and water. Oxygen may be oxygen radical. The oxidizing atmosphere enters the ends of between the layers of the multilayer graphene 1 and defects and grain boundaries of the planar graphene sheets, and is extended from these regions to a deeper part of the multilayer graphene 1. Then, the oxygen contained in the oxidizing atmosphere reacts with the third interlayer material 4 so as to generate the first interlayer material 2. Apart of the third interlayer material 4 may be partially oxidized so as to generate the second interlayer material (molybdenum oxychloride) 3. Alternatively, the part of the third interlayer material 4 may remain without being oxidized. In the case of partially oxidizing the third interlayer material 4, it is preferably oxidized under the atmosphere containing oxygen radical or ozone having high oxidizability at a decreased temperature for a shortened treating time. Between the plural planar graphene sheets, for example, chlorine molecules generated by the oxidation treatment may be present.

During the oxidation treatment, a mask may be formed so as to perform the oxidation treatment only to a selected interlayer region. Thereby, the region on which the first interlayer material 2 or the like is to be formed can be selected.

### Second Embodiment

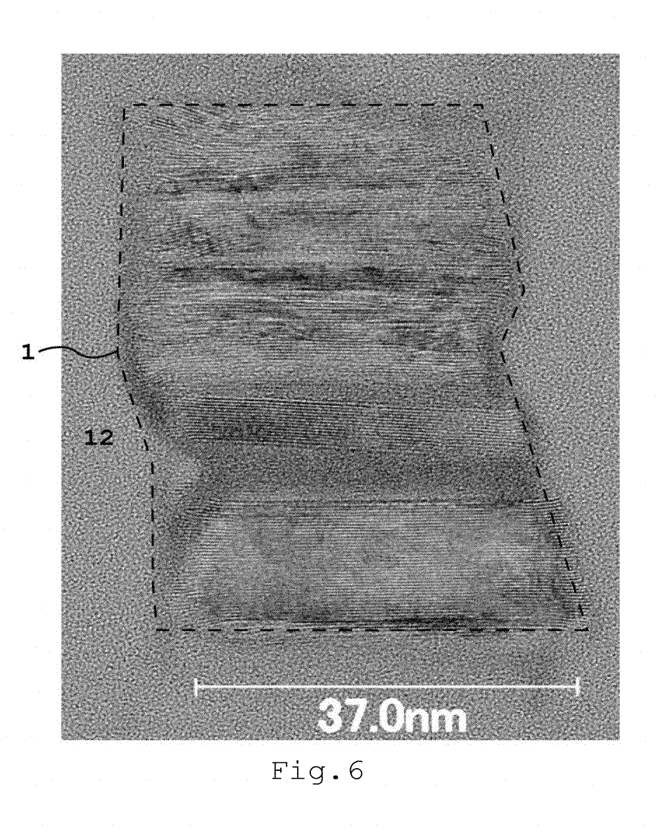

A second embodiment is a modified example of the graphene structure of the first embodiment. In a graphene wiring illustrated in the schematic cross-sectional view of FIG. 5, the graphene structure is provided between a first insulation film 6 and a second insulation film 7 above a substrate 11. Since a first interlayer material 2 and a second interlayer material 3 of the second embodiment are common with those of the other embodiment, explanation thereof will be omitted. Also, explanation of a multilayer graphene 1 and the like, which are common with those of the other embodiment, will be omitted.

The graphene wiring illustrated in the schematic cross-sectional view of FIG. 5 includes: the substrate 11; a metal unit 8 present on the substrate 11; the first insulation film 6 present on the substrate 11; the second insulation film 7 present on the substrate 11; the multilayer graphene 1 that is a laminate of planar graphene sheets 1G, 1H, 1I and 1J which are present between the first insulation film 6 and the second insulation film 7; and the first interlayer material 2, the second interlayer material 3 and the third interlayer material 4 that are present between the planar graphene sheets. An X-direction in the figure is a width direction of the wiring of the graphene structure, and a Y-direction is a height direction of the wiring of the graphene structure. In the second embodiment, a lamination direction of the planar graphene sheets 1G to 1J is the height direction of the wiring.

Since the planar graphene sheets 1G to 1J are the graphene sheets grown from the metal unit 8 that is a catalyst, one end of the graphene sheets 1G to 1J is connected with the metal unit 8. In the graphene structure of the second embodiment, the one end of the planar graphene sheets that compose the multilayer graphene 1 is connected with the metal unit, and other end is opened. The planar graphene sheets 1G to 1J are preferably graphene sheets formed by depositing carbon, which is derived from hydrocarbon such as ethylene gas solved in the substrate 11 and the metal unit 8, from the metal unit 8. In the graphene structure of the second embodiment, at least the first interlayer material 2 and the second interlayer material 3 are present between planar parts of the graphene sheets.

The metal unit 8 is preferably metal or alloy containing Fe, Ni, Co, Cu, Ti, Ta or Mo. The metal unit 8 is present continuously in a Z-direction on the substrate 11.

The substrate 11 is preferably a member having a hydrocarbon decomposition catalytic property and a carbon solid solubility such as aluminum oxide (Al₂O₃) and titanium oxide (TiO₂). On a main surface of the substrate 11, all of the metal unit 8, the first insulation film 6 and the second insulation film 7 are provided. By using these members as the substrate 11, even if the metal unit 8 is covered with the carbon deposited from the metal unit 8, the carbon continues to be supplied from the substrate 11 to the metal unit 8, so that the graphene sheets continue to be grown, thereby obtaining the multilayer graphene 1 that is the laminate of the planar parts of the graphene sheets as shown in FIG. 5.

The first insulation film 6 and the second insulation film 7 are insulative films. Between the first insulation film 6 and the second insulation film 7, there are: the multilayer graphene 1 that is the laminate of the planar graphene sheets; and the first interlayer material 2, the second interlayer material 3 and the third interlayer material 4 that are present between the layers of the multilayer graphene 1. The first insulation film 6 has a first main surface 6A that is a side surface perpendicular to the main surface of the substrate 11. Similarly, the second insulation film 7 has a second main surface 7A that is a side surface perpendicular to the main surface of the substrate 11.

It is preferable that the planar part of the graphene sheet 1G on one of outermost sides of the multilayer graphene 1 faces the first main surface 6A of the first insulation film 6, and the planar part of the graphene sheet 1G and the first main surface 6A of the first insulation film 6 are physically connected with each other. Further, it is preferable that the planar part of the graphene sheet 1J on other one of the outermost sides of the multilayer graphene 1 faces the second main surface 7A of the second insulation film 7, and the planar part of the graphene sheet 1J and the second main surface 7A of the second insulation film 7 are physically connected with each other.

The multilayer graphene 1 of the graphene structure of the second embodiment has a different form from that of the graphene structure of the first embodiment, but the graphene structures of both embodiments are common in that the first interlayer material 2 that is the multimer is stable and contributes to the resistant reduction of the multilayer graphene 1. As described above, by allowing the first interlayer material 2 to be present between the layers of the multilayer graphene 1, the stable and low-resistance graphene structure can be obtained.

### Example

A multilayer graphene 1 that was multicrystal was produced, and was treated in an atmosphere containing molybdenum chloride and inert gas. Subsequently, the gas was replaced with an atmosphere containing oxygen gas, and the multilayer graphene 1 treated by molybdenum chloride was subjected to oxidation treatment, thereby obtaining a graphene structure. Then, the graphene structure was coated with silicone resin 12 so as to be covered therewith, and a cross section to be imaged by a microscope was prepared.

Next, the prepared cross section was imaged with magnification of 2,000,000 times by using a TEM. FIG. 6 shows a TEM image taken with the magnification of 2,000,000 times. In the TEM image of FIG. 6, broken lines are drawn so as to show the multilayer graphene 1 and the silicone resin 12 definitely. Linear parts in the figure, which are continuous in a transverse direction in the figure and are overlapped with each other, are the multilayer graphene 1 that is a laminate of planar graphene sheets. In a region of the multilayer graphene 1 in the figure, irregular black belt-shaped patterns are shown. These are interlayer materials that are present between the layers of the multilayer graphene 1.

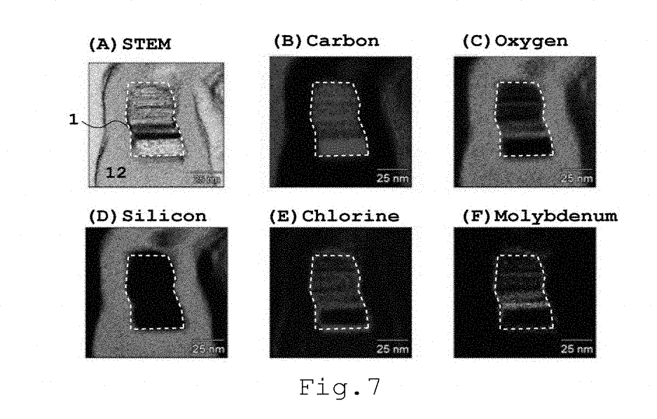

Since the presence of the interlayer materials were observed between the layers of the multilayer graphene 1 by the TEM image, imaging and chemical element mapping were performed with the electron microscope to identify the interlayer materials. The prepared section sample of the multilayer graphene 1 was imaged with magnification of 1,000,000 times by using a STEM. A STEM image with no chemical element mapping is shown in FIG. 7(A). In FIG. 7(A), broken lines are drawn so as to show the multilayer graphene 1, the substrate 11 and the silicone resin 12 definitely. Then, element analysis of carbon, oxygen, silicon, chlorine and molybdenum was performed with an EDX so as to map them. FIG. 7(B) shows an image with carbon mapping. FIG. 7(C) shows an image with oxygen mapping. FIG. 7(D) shows an image with silicon mapping. FIG. 7(E) shows an image with chlorine mapping. FIG. 7(F) shows an image with molybdenum mapping. Incidentally, white spot regions in FIG. 7 represent positions where the corresponding elements were present. In the figures with the chemical element mapping, a region surrounded by the broken lines is the region of the multilayer graphene 1.

Focusing on the region of the multilayer graphene 1 in the images with the chemical element mapping, it can be realized that molybdenum, chlorine, carbon and oxygen were present as a whole. Further, it can be ascertained that oxygen, chlorine and molybdenum were present with high concentration in band shapes between the layers of the multilayer graphene 1. In particular, in these band-shaped regions, significantly high concentration of oxygen and molybdenum were present, and high concentration of oxygen and molybdenum were present also at the ends of the multilayer graphene 1. Oxygen and molybdenum had corresponding belt-shaped distributions. Since the silicone resin 12 contained carbon, carbon was observed on a side of the silicone resin 12.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A graphene structure comprising:
multilayer graphene laminated with graphene sheets; and
a first interlayer material being present between the graphene sheets of the multilayer graphene and containing a multimer of molybdenum oxide.

2. The structure according to claim 1, further comprising a second interlayer material being present between the graphene sheets of the multilayer graphene, and containing a multimer of molybdenum oxychloride.

3. The structure according to claim 1, wherein a width of the multilayer graphene is 5 nm or more and 20 nm or less.

4. The structure according to claim 1, further comprising a third interlayer material being present between the graphene sheets, and containing a multimer of molybdenum chloride.

5. The structure according to claim 1, further comprising a fourth interlayer material being present between the plural graphene sheets, and containing chlorine.

6. The structure according to claim 1, wherein the graphene sheets are planar graphene sheets.
